(19) United States
(12) Patent Application Publication
(10) Pub. No.: US 2017/0184891 A1
(43) Pub. Date: Jun. 29, 2017

(54) THIN FILM TRANSISTOR ARRAY SUBSTRATE

(71) Applicant: SHENZHEN CHINA STAR OPTOELECTRONICS TECHNOLOGY CO., LTD., Shenzhen (CN)

(72) Inventor: Yang ZHAO, Shenzhen (CN)

(73) Assignee: Shenzhen China Star Optoelectronics Technology Co., Ltd., Shenzhen (CN)

(21) Appl. No.: 14/907,300

(22) PCT Filed: Jan. 12, 2016
(86) PCT No.: PCT/CN2016/070704

§ 371 Date: Jan. 25, 2016

(30) Foreign Application Priority Data
Dec. 25, 2015 (CN) 201510993319.3

(51) Int. Cl. G02F 1/1368; G02F 1/1343; H01L 27/12

(52) U.S. Cl. CPC G02F 1/1368; H01L 27/1248; G02F 1/13439; G02F 2201/40; G02F 2001/136222

(57) ABSTRACT

A thin film transistor array substrate is provided with a thin film transistor layer; a color resist layer disposed on the thin film transistor layer, and having a plurality of color resist units and a plurality of openings; and a transparent electrode layer electrically connected with the thin film transistor layer through the openings. The openings are provided with a first opening extending across two adjacent color resist units. The thin film transistor array substrate has larger color resist openings and common openings used by two thin film transistors so as to improve the aperture ratio and the transmittance of the thin film transistor array substrate.

### FIELD OF THE INVENTION

The present invention relates to a thin film transistor array substrate, and more particularly to a thin film transistor array substrate with a higher aperture ratio and an enhanced transmittance.

### BACKGROUND OF THE INVENTION

Currently, in a variety of display technologies, liquid crystal display has been widely accepted as a mature technology. Liquid crystal displays (LCD) use the electro-optic effect of the liquid crystal, and the intensity of the light transmitted through the color resistance from a backlight module is adjusted by controlling the transmittance and reflectance of the liquid crystal molecules through a circuit to achieve different gray levels and different color displays.

Generally, a liquid crystal display panel includes an array substrate, a color filter substrate, and a liquid crystal layer disposed between the array substrate and the color filter substrate. The array substrate configures several thin film transistors as power switches of pixels to control liquid crystal molecules of the pixels, so that the liquid crystal display panel shows colorful images. In another type of liquid crystal display panel, the color resist layer of the color filter substrate is transferred to form on the array substrate, that is an array substrate having a color resist layer (i.e. called color filter on array, COA), in order to simplify the assembly of the liquid crystal display panel. However, the color resist layer (RGB layer) coated on the COA type array substrate is not fully transparent, which causes loss of the light intensity passed through the array substrate, so that the transmittance is reduced. Moreover, the openings of the color resist layer on the array substrate used for conducting the transparent electrode and the TFT electrode have a distance of at least 3 microns from the data lines to avoid peeling of the color resist layer, and the promotion of the aperture ratio is thus limited.

It is therefore necessary to provide a thin film transistor array substrate to provide a higher aperture ratio and a higher transmittance to solve the problems existing in the conventional technology as described above.

### SUMMARY OF THE INVENTION

A primary object of the present invention is to provide a thin film transistor array substrate having a larger opening of the color resist and a common opening used by two thin film transistors to improve the aperture ratio and further enhance the transmittance of the thin film transistor array substrate.

To achieve the above object, the present invention provides a thin film transistor array substrate which comprises a thin film transistor layer; a color resist layer disposed on the thin film transistor layer, and including a plurality of color resist units and a plurality of openings; and a transparent electrode layer electrically connected with the thin film transistor layer through the openings; wherein the plurality of openings comprise a first opening extending across two of the adjacent color resist units.

Furthermore, another embodiment of the present invention provides a thin film transistor array substrate which comprises a thin film transistor layer; a color resist layer disposed on the thin film transistor layer, and including a plurality of color resist units and a plurality of openings; and a transparent electrode layer electrically connected with the thin film transistor layer through the openings; wherein the plurality of openings comprise a first opening which is rectangular and has two long sides and two short sides, wherein the two short sides are respectively located at two of the adjacent color resist units.

In one embodiment of the present invention, the thin film transistor layer comprises a gate layer and a drain layer.

In one embodiment of the present invention, the transparent electrode layer extends into the first opening so that the color resist units are electrically connected with the drain layer.

In one embodiment of the present invention, the transparent electrode layer extends into the first opening so that the drain layer is electrically connected with the gate layer through the transparent electrode layer.

In one embodiment of the present invention, the first opening has a first sidewall and a second sidewall respectively located at the two adjacent color resist units and connected with each other to form the first opening.

In one embodiment of the present invention, the thin film transistor layer comprises a plurality of thin film transistors and at least two of the thin film transistors are independently electrically connected with the transparent electrode layer through the first opening.

In one embodiment of the present invention, the at least two of the thin film transistors are located at the two adjacent color resist units.

The abovementioned features adopted by the present invention to achieve the above and other objects can be best understood by referring to the following detailed description of the preferred embodiments and the accompanying drawings.

### DESCRIPTION OF THE DRAWINGS

FIG. 1 is a top view for partially showing a thin film transistor array substrate according to one embodiment of the present invention.

FIG. 2 is a cross-sectional view taken along a line A-A in FIG. 1 for showing the thin film transistor array substrate according to one embodiment of the present invention.

### DETAILED DESCRIPTION OF THE PREFERRED EMBODIMENTS

The detailed description of the following embodiments is used for exemplifying the specific embodiments of the present invention by referring to the accompany drawings. Furthermore, directional terms described by the present invention, such as upper, lower, front, back, left, right, inner, outer, side, etc., are only directions by referring to the accompanying drawings, and thus the directional terms are used to describe and understand the present invention, but the present invention is not limited thereto.

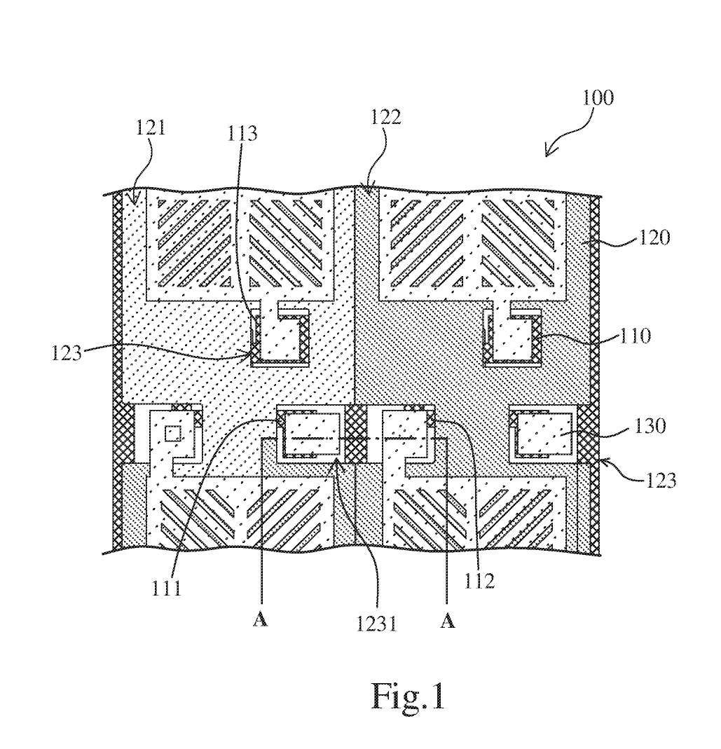

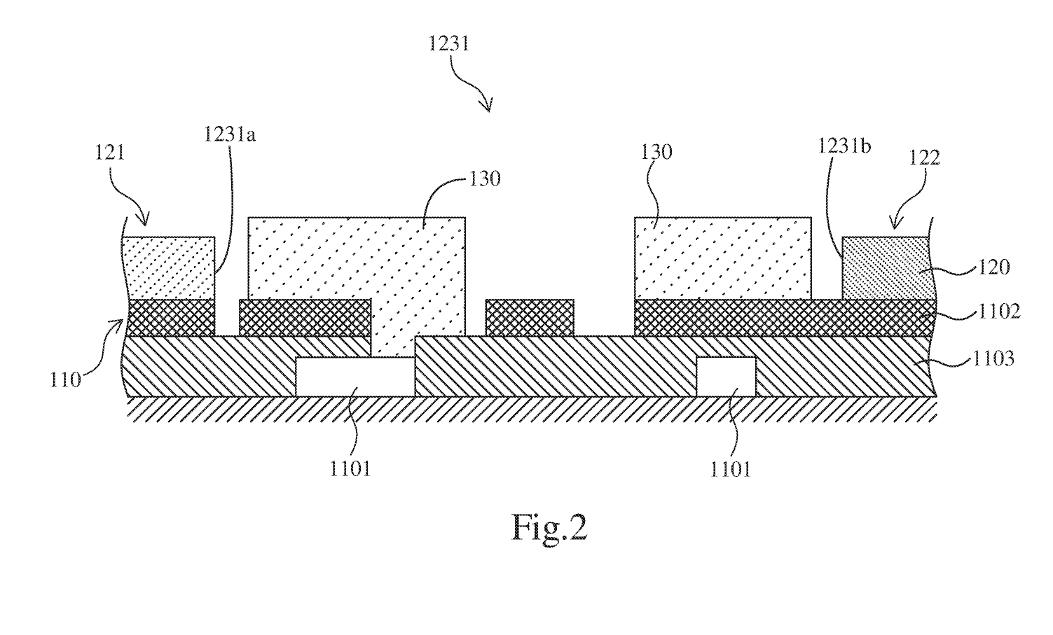

Referring to FIG. 1 and FIG. 2, a thin film transistor array substrate 100 according to one embodiment of the present invention is illustrated, wherein FIG. 1 shows a top view; FIG. 2 shows a cross-sectional view taken along a line A-A in FIG. 1. The thin film transistor array substrate 100 of the present invention belongs to a COA (color filter on array) type array substrate which is to directly form a color resist layer on the array substrate. The thin film transistor array substrate 100 mainly comprises a thin film transistor layer 110; a color resist layer 120; and a transparent electrode layer 130. The color resist layer 120 is disposed on the thin film transistor layer 110 and has a plurality of color resist units, such as R color resist 121 of red color, G color resist 122 of green, B color resist of blue, and Y color resist of yellow. The R color resist 121 and the G color resist 122 are exemplified hereafter for representing a first color resist unit and a second color resist unit adjacent on left and right, or adjacent by the top and bottom.

Furthermore, as shown in FIG. 1, the thin film transistor layer 110 can form a first thin film transistor 111, a second thin film transistor 112, and a third thin film transistor 113 corresponding to each of the color resist units used for power switches of the color resist units, but it is not limited thereto. The color resist layer 120 has a plurality of openings 123 located at different positions. The transparent electrode layer 130 is electrically connected with the thin film transistor layer 110 through the openings 123. In the plurality of the openings 123, a first opening 1231 extends across two of the adjacent color resist units (such as the R color resist 121 and the G color resist 122).

Referring to FIG. 2 again, the thin film transistor layer 110 comprises a gate layer 1101, a drain layer 1102, and an insulating layer 1103. In the range of the G color resist 122, the transparent electrode layer 130 extends into the first opening 1231 so that the G color resist 122 is electrically connected with the drain layer 1102 to conduct the pixel. In addition, in the range of the R color resist 121, the transparent electrode layer 130 also extends into the first opening 1231 so that the drain layer 1102 is electrically connected with the gate layer 1101 through the transparent electrode layer 130. The first opening 1231 has a first sidewall 1231a and a second sidewall 1231b respectively located at the R color resist 121 and the G color resist 122, and connected with each other to form the first opening 1231. Preferably, the first opening 1231 is rectangular, and has two long sides and two short sides, wherein the two short sides are respectively located at the two adjacent color resist unit, such as the R color resist 121 and the G color resist 122.

Preferably, as shown in FIG. 1, at least two of the thin film transistors, such as the first transistor 111 corresponding to the R color resist 121 and the second transistor 112 corresponding to the G color resist 122, are independently electrically connected with the transparent electrode layer 130 which is patterned to form independent conductive sections.

It is understood that at least two thin film transistors share a common opening formed on two adjacent color resist units but independently connect with the different conductive sections of the transparent electrode layer thereby increasing the area of the opening, raising the total aperture ratio, and further improving the transmittance of the thin film transistor array substrate. According to the thin film transistor array substrate of the present invention, the transmittance can be enhanced from 37.5% to at least 40.35%.

As mentioned above, the higher aperture ratio can be obtained by increasing the area of the opening of the color resist layer and making at least two thin film transistors share the same opening. The transmittance of the thin film transistor array substrate can also be improved effectively.

The present invention has been described with preferred embodiments thereof and it is understood that many changes and modifications to the described embodiments can be carried out without departing from the scope and the spirit of the invention that is intended to be limited only by the appended claims.

1. A thin film transistor array substrate, comprising:
a thin film transistor layer;
a color resist layer disposed on the thin film transistor layer, and including a first color resist, a second color resist adjacent to the first color resist, and a plurality of openings comprising at least one first opening; and
a transparent electrode layer disposed on the color resist layer and extending into the first opening to electrically connect with the thin film transistor layer;
wherein the first opening is rectangular and has two long sides and two short sides, wherein the two short sides are respectively located at the first color resist and the second color resist.

2. The thin film transistor array substrate according to claim 1, wherein the thin film transistor layer comprises a gate layer and a drain layer.

3. The thin film transistor array substrate according to claim 2, wherein at least one of the first color resist and the second color resist is electrically connected with the drain layer through the first opening.

4. The thin film transistor array substrate according to claim 2, wherein the drain layer is electrically connected with the gate layer through the transparent electrode layer extending into the first opening.

5. The thin film transistor array substrate according to claim 1, wherein the thin film transistor layer comprises a plurality of thin film transistors and at least two of the thin film transistors are independently electrically connected with the transparent electrode layer through the first opening.

6. The thin film transistor array substrate according to claim 5, wherein the at least two of the thin film transistors are located at the first color resist and the second color resist.

7. A thin film transistor array substrate, comprising:
a thin film transistor layer;
a color resist layer disposed on the thin film transistor layer, and including a first color resist, a second color resist adjacent to the first color resist, and a plurality of openings comprising at least one first opening; and
a transparent electrode layer disposed on the color resist layer and extending into the first opening to electrically connect with the thin film transistor layer;
wherein the first opening extending across the first adjacent color resist and the second color resist.

8. The thin film transistor array substrate according to claim 7, wherein the thin film transistor layer comprises a gate layer and a drain layer.

9. The thin film transistor array substrate according to claim 8, wherein at least one of the first color resist and the second color resist is electrically connected with the drain layer through the first opening.

10. The thin film transistor array substrate according to claim 8, wherein the drain layer is electrically connected with the gate layer through the transparent electrode layer extending into the first opening.

11. The thin film transistor array substrate according to claim 7, wherein the first opening has a first sidewall and a second sidewall respectively located at the first color resist and the second color resist, and connected with each other to form the first opening.

12. The thin film transistor array substrate according to claim 7, wherein the thin film transistor layer comprises a plurality of thin film transistors and at least two of the thin film transistors are independently electrically connected with the transparent electrode layer through the first opening.

13. The thin film transistor array substrate according to claim 12, wherein the at least two of the thin film transistors are respectively located at the first color resist and the second color resist.
